(19) United States
(12) Patent Application Publication
(10) Pub. No.: US 2026/0367387 A1
(43) Pub. Date: Nov. 19, 2026

(54) MICROELECTROMECHANICAL SYSTEMS DEVICE AND METHOD FOR FORMING THE SAME

(71) Applicants: TAIWAN SEMICONDUCTOR MANUFACTURING COMPANY, LTD., Hsinchu (TW); NATIONAL TSING HUA UNIVERSITY, HSINCHU CITY (TW)

(72) Inventors: Jin Rong NG, Tainan City (TW); Weileun FANG, Hsinchu City (TW); Sheng Kai YEH, Taichung City (TW); Shih Chi LIU, Hsinchu City (TW); Chi-Yuan SHIH, Hsinchu County (TW); Shih-Fen HUANG, Hsinchu County (TW)

(73) Assignees: TAIWAN SEMICONDUCTOR MANUFACTURING COMPANY, LTD., Hsinchu (TW); NATIONAL TSING HUA UNIVERSITY, HSINCHU CITY (TW)

(21) Appl. No.: 19/750,790

(22) Filed: Jul. 22, 2026

Related U.S. Application Data
(62) Division of application No. 18/630,623, filed on Apr. 9, 2024.

(51) Int. Cl. G02B 26/08; B81B 7/00; B81C 1/00

(52) U.S. Cl. CPC G02B 26/0833; B81B 7/0016; B81C 1/00825; B81B 2201/042; B81B 2203/0118; B81C 2201/0132

(57) ABSTRACT

A microelectromechanical systems (MEMS) device includes a mirror structure, a frame, a first cantilever and a second cantilever. The mirror structure is suspended in the frame by the first cantilever and the second cantilever. The first cantilever includes a first sub-cantilever connected to the frame; a second sub-cantilever connected to the mirror structure; and a third sub-cantilever connecting the first sub-cantilever to the second sub-cantilever. Each of the first sub-cantilever and the third sub-cantilever comprises a first bottom electrode; a first piezoelectric layer over the first bottom electrode; and first and second electrodes over the first piezoelectric layer, wherein the first and second electrodes are separated from each other.

### PRIORITY CLAIM AND CROSS-REFERENCE

This present application is a divisional application of U.S. Patent Application Serial Number 18/630,623, filed Apr. 09, 2024, which is herein incorporated by reference in their entirety.

### BACKGROUND

Micro electro mechanical systems (MEMS) devices are known that have a mirror structure obtained using a semiconductor material technology. Such MEMS devices are, for example, used in portable apparatuses, such as portable computers, laptops, notebooks (including ultra-thin notebooks), PDAs, tablets, mobile phones or smartphones, for optical applications, in particular for directing one or more beams of light radiation generated by a light source in desired patterns and/or directions.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are respectively top and bottom views of a microelectromechanical systems (MEMS) device in accordance with some embodiments of the present disclosure.

FIG. 1C is a cross-sectional view of the MEMS device taken along line A-A and line B-B in FIGS. 1A and 1B.

FIG. 1D is a cross-sectional view of the MEMS device taken along a rotation axis AX in FIGS. 1A and 1B.

FIG. 1E is an enlarged view of a portion of FIG. 1A.

FIGS. 2-9 are cross-sectional views of intermediate stages in formation of a MEMS device in accordance with some embodiments of the present disclosure.

FIGS. 10A and 10B are respectively top and bottom views of a MEMS device in accordance with some embodiments of the present disclosure.

FIGS. 11A and 11B are respectively top and bottom views of a MEMS device in accordance with some embodiments of the present disclosure.

FIGS. 12A and 12B are respectively top and bottom views of a MEMS device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” shall generally mean within 20 percent, or within 10 percent, or within 5 percent of a given value or range. Numerical quantities given herein are approximate, meaning that the term “around,” “about,” “approximately,” or “substantially” can be inferred if not expressly stated.

LiDAR (Light Detection and Ranging) has been widely used in various field, such as topography, three-dimensional imaging, spectroscopy. Recently, LiDAR have attached much attention in the automotive field as the key component for high level self-driving systems. Compared with other technique of self-driving sensor, such as radar and stereo camera, LiDAR have the advantage of provide high accurate and high resolution in 3D surrounding measurement in harsh environment. Micro electro mechanical systems (MEMS) LiDAR has advantages of low cost through batch fabrication and high operation frequency, high resolution, low power consumption. Piezoelectric MEMS LiDAR further has advantages of low power consumption, compact size and large generated force.

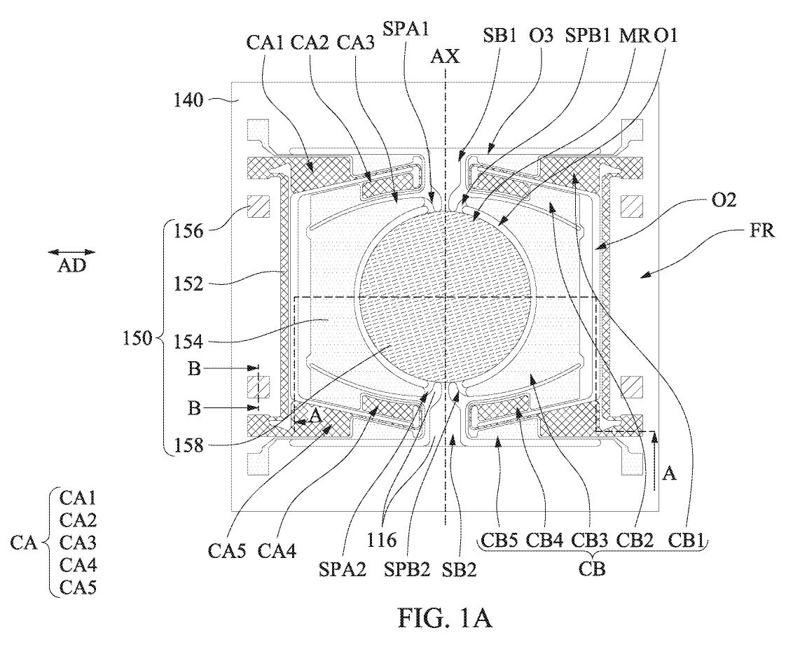

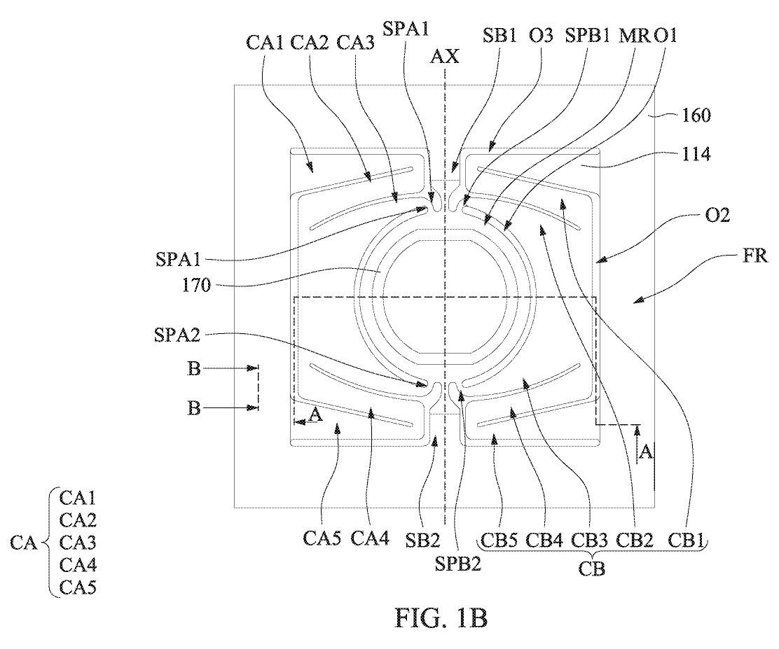

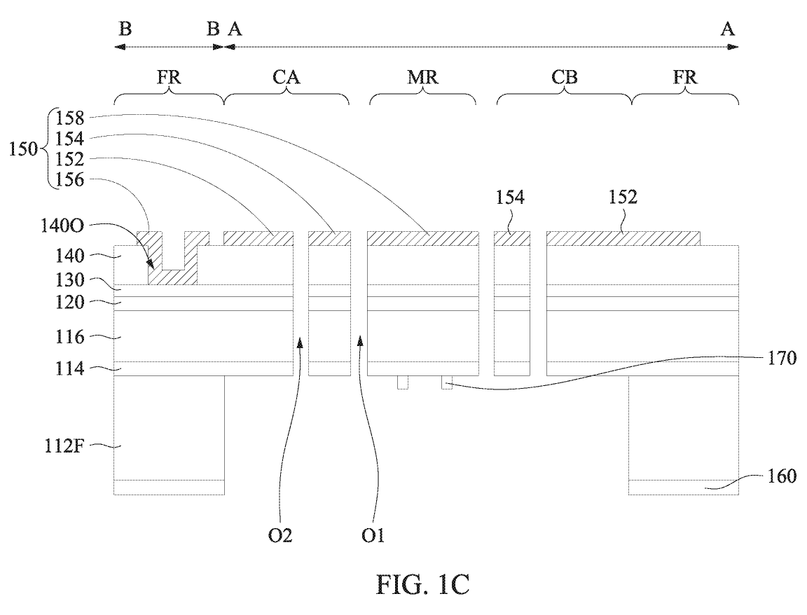

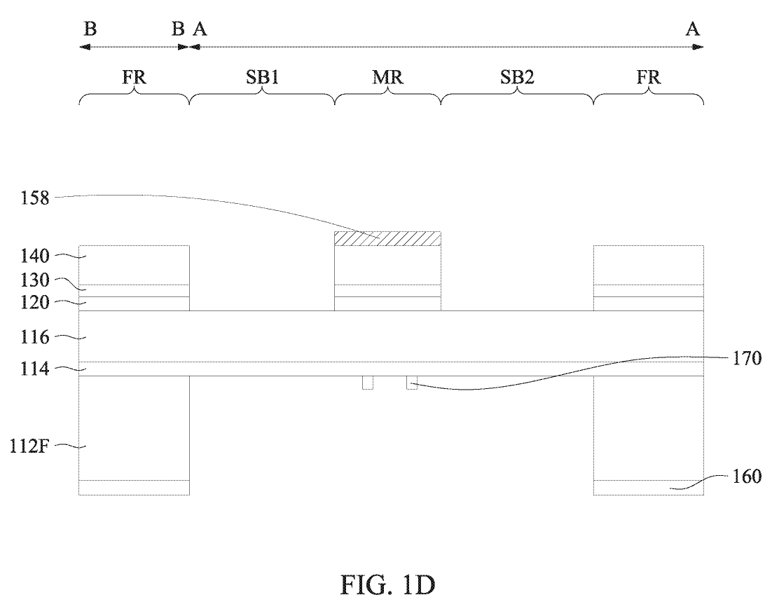

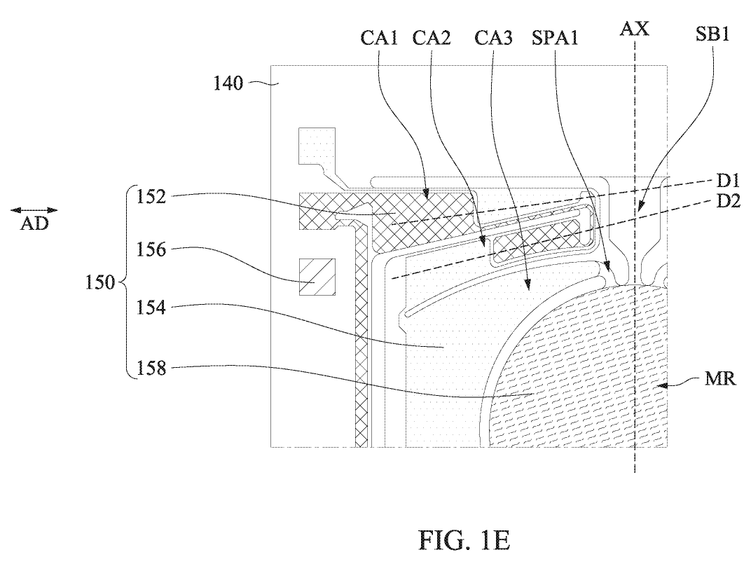

FIGS. 1A and 1B are respectively top and bottom views of a microelectromechanical systems (MEMS) device in accordance with some embodiments of the present disclosure. FIG. 1C is a cross-sectional view of the MEMS device taken along line A-A and B-B in FIGS. 1A and 1B. FIG. 1D is a cross-sectional view of the MEMS device taken along a rotation axis AX in FIGS. 1A and 1B. The MEMS device includes a frame 112F, a dielectric layer 114, a semiconductor layer 116, a dielectric layer 120, a first electrode layer 130, a piezoelectric layer 140, and a second electrode layer 150, a backside metal layer 160, and a rib structure 170. The dielectric layer 114, the semiconductor layer 116, the dielectric layer 120, the first electrode layer 130, the piezoelectric layer 140, and the second electrode layer 150 are supported by the frame 112F. The second electrode layer 150 has separated electrodes 152-158. Stated differently, electrodes 152-158 are electrically isolated from each other. The piezoelectric layer 140 is sandwiched between the electrodes 152, 154, and 158 of the second electrode layer 150 and the first electrode layer 130. The electrodes 152-154 and 158 are spaced apart from the first electrode layer 130. The electrode 156 is in contact with the first electrode layer 130 for serving as conductive paths/pads to the first electrode layer 130. The backside metal layer 160 is formed on a backside of the frame 112F.

In FIGS. 1A and 1B, the MEMS device may include a first cantilever region CA, a second cantilever region CB, a mirror region MR, and shock buffer regions SB1, SB2, and a frame region FR. The mirror region MR is suspended, for example being spaced apart from the frame region FR by the first cantilever region CA, the second cantilever region CB, and the shock buffer regions SB1, SB2. The electrode 158 may be located in the mirror region MR and serve as a reflective mirror, in which the reflective mirror (i.e., the electrode 158) is laterally aligned to the electrodes 152 and 154. The mirror region MR can rotate along a rotation axis AX. In the context, the first cantilever region CA, the second cantilever region CB, the mirror region MR, the shock buffer regions SB1, SB2, and the frame region FR can be respectively referred to as a first cantilever, a second cantilever, a mirror structure, shock buffers, and a frame.

In the present embodiments, the shock buffer regions SB1 and SB2 connect opposite ends of the mirror region MR along the rotation axis AX to the frame region FR, thereby enhances the robustness of the device and reduce the wobbling phenomenon. The frame region FR may serve as an anchor for the mirror region MR through the shock buffer regions SB1 and SB2. The shock buffer regions SB1 and SB2 may have elongated shaped extends along the rotation axis AX. Each of the shock buffer regions SB1 and SB2 has a first end connected with the mirror region MR and a second end connected with the frame region FR, the first and second ends of the shock buffer regions SB1 and SB2 are arranged along the rotation axis AX. The shock buffer can increase the robustness of the out-of-plane of the mirror and reduce the wobbling phenomenon. In some embodiments, a width of the shock buffer regions SB1 and SB2 may increase from the mirror region MR to the frame region FR.

The first cantilever region CA and second cantilever region CB may serve as actuator that would deform and provide the driving force to rotate the mirror when the voltage is applied on the electrodes 152, 154, and 156. Each of the first cantilever region CA and second cantilever region CB has a first end connected with the frame 112F and a second end connected with the mirror region MR. The MEMS device may further include connection regions SPA1 and SPA2 between the mirror region MR and the first cantilever region CA, and connection regions SPB1 and SPB2 between the mirror region MR and the second cantilever region CB. The connection regions SPA1 and SPA2 are spaced apart from the rotation axis AX. The connection regions SPA1 and SPA2 and the shock buffer regions SB1 and SB2 may be free of the second electrode layer 150, the piezoelectric layer 140, and the first electrode layer 130.

The rib structure 170 is formed on a backside of the dielectric layer 114 in the mirror region MR, to provide a structural support to the mirror region MR, thereby maintaining a flatness of the mirror region MR. The rib structure 170 may be one or more rings, one or more straight lines, the like, or the combination thereof. A sum size of the rib structure 170 is smaller than the mirror region MR.

The electrodes 152 and 154 may be located in the first cantilever region CA and the second cantilever region CB to provide a vertical displacement through exerting different voltage phase across different regions of the piezoelectric layer 140, thereby providing (rotational/twist) forces to the mirror region MR. Stated differently, voltages with phase variation may be applied on the electrodes 152 and 154 respectively for providing (rotational/twist) forces to the mirror region MR. For example, a positive voltage is applied on the electrode 152, and a negative voltage is applied on the electrode 154. Alternatively, a positive voltage is applied on the electrode 154, and a negative voltage is applied on the electrode 152. The electrodes 152/154 of the two cantilever regions CA and CB can be applied with different voltages for individually operation and control.

Openings O1 may be located between the mirror region MR and the first cantilever region CA and between the mirror region MR and the second cantilever region CB. Openings O2 and O3 may be located between the frame region FR and the first cantilever region CA and between the frame region FR and the second cantilever region CB. The openings O1 and O3 limit the connection regions (or connection springs) SPA1 and SPA2 between the mirror region MR and the first cantilever region CA at two positions respectively adjacent the shock buffer regions SB1, SB2, and limit the connection region (or connection spring) SPB1 and SPB2 between the mirror region MR and the second cantilever region CB at two positions respectively adjacent the shock buffer regions SB1, SB2. Openings O2 and O3 may be located between the frame region FR and the first cantilever region CA and between the frame region FR and the second cantilever region CB. The openings O2 and O3 limit the connection point between the frame region FR and the first cantilever region CA at two positions respectively laterally aligned the shock buffer regions SB1, SB2, and limit the connection point between the mirror region MR and the second cantilever region CB at two positions respectively laterally aligned the shock buffer regions SB1, SB2.

In some embodiments of the present embodiments, the openings O2 and O3 extend into the first cantilever region CA, such that the first cantilever region CA has sub-cantilever regions CA1-CA5. The sub-cantilever regions CA3 is connected to the mirror region MR, for example, through the connection regions (connection springs) SPA1 and SPA2. The sub-cantilever regions CA1 and CA5 are respectively connected to the frame region FR. The sub-cantilever region CA2 connects the sub-cantilever region CA1 to the sub-cantilever region CA3, and the sub-cantilever region CA4 connects the sub-cantilever region CA5 to the sub-cantilever region CA3. Each of the sub-cantilever regions CA1, CA2, CA4, CA5 has two electrodes 152 and 154. The sub-cantilever region CA3 may extend across the mirror region MR along a direction parallel with a rotation axis AX of the mirror region MR. In the depicted embodiments, the sub-cantilever region CA3 has one electrode 154 and no electrode 152. In some other embodiments, the sub-cantilever region CA3 has one electrode 152 and no electrode 154. In some other embodiments, the sub-cantilever region CA3 may have two electrodes 152 and 154. The electrodes 152 of the sub-cantilever regions CA1, CA2, CA4, CA5 are electrically connected with each other, and the electrodes 154 of the sub-cantilever regions CA1-CA5 are electrically connected with each other. Through the configuration, a large vertical displacement by accumulating the displacement of each is provided. The electrodes 152 and 154 may extend from the first cantilever region CA to the frame region FR, thereby serving as conductive paths/pads for electrical connection. The electrode 156 may be located in the frame region FR and serving as conductive paths/pads to the first electrode layer 130.

Similarly, in some embodiments of the present embodiments, the openings O2 and O3 extend into the second cantilever region CB, such that the second cantilever region CB has sub-cantilever regions CB1-CB5. The sub-cantilever region CB3 is connected to the mirror region MR, for example, through the connection regions (connection springs) SPB1 and SPB2. The sub-cantilever regions CB1 and CB5 are respectively connected to the frame region FR. The sub-cantilever region CB2 connects the sub-cantilever region CB1 to the sub-cantilever region CB3, and the sub-cantilever region CB4 connects the sub-cantilever region CB5 to the sub-cantilever region CB3. Each of the sub-cantilever regions CB1, CB2, CB4, CB5 has two electrodes 152 and 154. The sub-cantilever region CB3 may extend across the mirror region MR along a direction parallel with a rotation axis AX of the mirror region MR. In the depicted embodiments, the sub-cantilever region CB3 has one electrode 154 and no electrode 152. In some other embodiments, the sub-cantilever region CB3 has one electrode 152 and no electrode 154. In some other embodiments, the sub-cantilever region CB3 may have two electrodes 152 and 154. The electrodes 152 of the sub-cantilever regions CB1, CB2, CB4, CB5 are electrically connected with each other, and the electrodes 154 of the sub-cantilever regions CB1-CB5 are electrically connected with each other. Through the configuration, a large vertical displacement by accumulating the displacement of each is provided. The electrodes 152 and 154 may extend from the second cantilever region CB to the frame region FR, thereby serving as conductive paths/pads for electrical connection. In the context, the sub-cantilever regions CA1-CA5 and CB1-CB5 may be referred to as sub-cantilevers.

In some embodiments of the present disclosure, for enlarging the vertical displacement, the sub-cantilever regions CA1, CA2, CA4, CA5 and/or the sub-cantilever regions CB1, CB2, CB4, CB5 may have an elongated shape. The elongated shape may extend along a direction AD orthogonal to the rotation axis AX. In some embodiments, a length of the sub-cantilever regions CA1, CA2, CA4, CA5 measured along the direction AD may be greater than a length of the sub-cantilever regions CA1, CA2, CA4, CA5 measured along the direction of the rotation axis AX. In some embodiments, since the piezoelectric layer 140 shows anisotropic behavior in its deformation when being applied with voltages, the elongated shape in the sub-cantilever regions CA1, CA2, CA4, CA5 and/or the sub-cantilever regions CB1, CB2, CB4, CB5 would result in different deformation amounts along the rotation axis AX and the direction AD. The multi-cantilever (e.g., tri-cantilever) design provides higher vertical displacement, which ensures the scanning mirror to have a good performance in optical scanning angle. In some embodiments, a width of the connection regions SPA1 and SPA2 is less than a width of the sub-cantilever regions CA1-CA5 of the first cantilever region CA, a width of the connection regions SPB1 and SPB2 is less than a width of the sub-cantilever regions CB1-CB5 of the second cantilever region CB.

FIG. 1E is an enlarged view of a portion of FIG. 1A. As shown in FIG. 1E, an angle between a lengthwise direction of the sub-cantilever regions CA1, CA2, CA4, CA5 and/or the sub-cantilever regions CB1, CB2, CB4, CB5 and the direction AD perpendicular to the rotation axis AX of the mirror region MR is in a range from about 0 degree to about 40 degrees in a top view. In some embodiments, the angle between a lengthwise direction D2 of the sub-cantilever region CA2 and the direction AD may be greater than the angle between the lengthwise direction D1 of the sub-cantilever region CA1 and the direction AD. For example, the angle between a lengthwise direction D1 of the sub-cantilever region CA1 and the direction AD may be in a range from about 0 degree to about 10 degrees in a top view, and the angle between a lengthwise direction D2 of the sub-cantilever region CA2 and the direction AD may be in a range from about 10 degree to about 20 degrees in a top view. The sub-cantilever regions CA4 and CA5 may have symmetrical configurations as that of the sub-cantilever regions CA2 and CA1, and thus not repeated herein. The sub-cantilever regions CB1-CB5 may have symmetrical configurations as that of the sub-cantilever regions CA1-CA5, and thus not repeated herein.

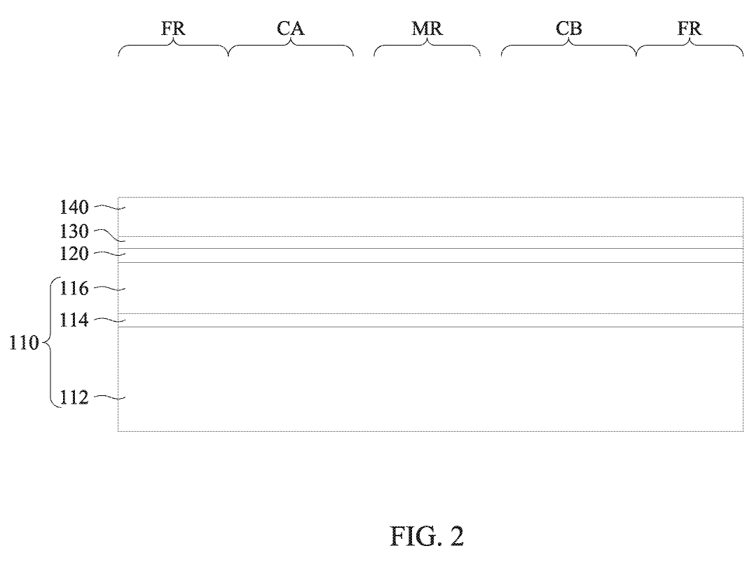

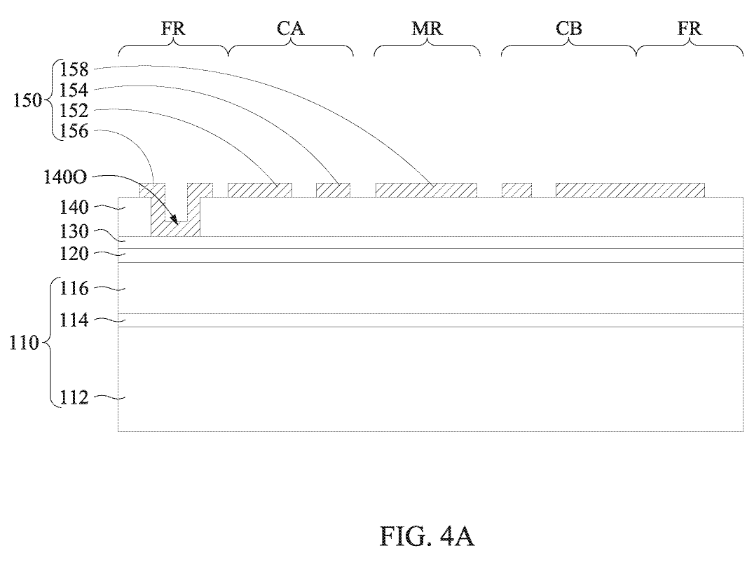

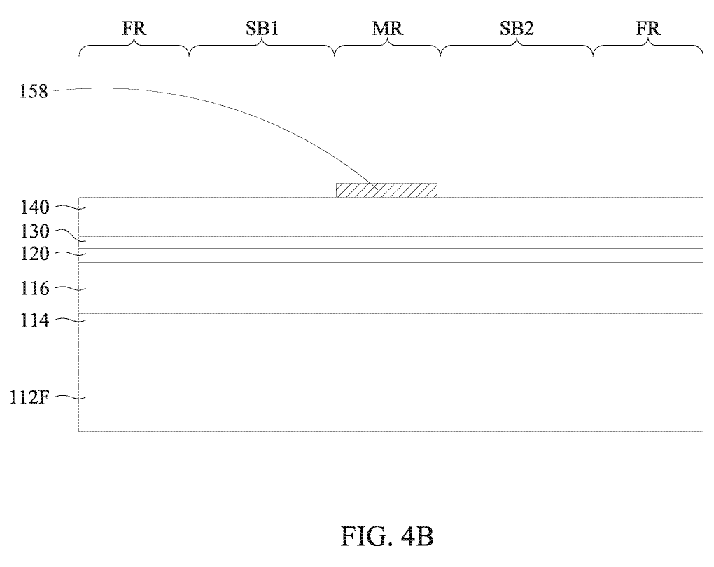

FIGS. 2-9 are cross-sectional views of intermediate stages in formation of a MEMS device in accordance with some embodiments of the present disclosure. The cross-sectional views of FIGS. 2, 3, 4A, 5A, 6A, 7-9 are taken along line A-A and line B-B in FIGS. 1A and 1B. The cross-sectional views of FIGS. 4B, 5B, 6B are taken along the rotation axis AX in FIGS. 1A and 1B. It is understood that additional steps may be provided before, during, and after the steps shown by FIGS. 2-9, and some of the steps described below can be replaced or eliminated for additional embodiments of the method. The order of the operations/processes may be interchangeable.

Reference is made to FIG. 2. A semiconductor substrate 110 is provided. The semiconductor substrate 110 may be a semiconductor-on-insulator (SOI) substrate including a base substrate 112, a dielectric layer 114 over the base substrate 112, and a semiconductor layer 116 over the dielectric layer 114. The base substrate 112 may be a bulk substrate, such as bulk silicon substrate. The base substrate 112 may include silicon. Alternatively, the base substrate 112 may include other elementary semiconductor such as germanium. The base substrate 112 may also include a compound semiconductor such as silicon carbide, gallium arsenic, indium arsenide, and indium phosphide. The base substrate 112 may include an alloy semiconductor such as silicon germanium, silicon germanium carbide, gallium arsenic phosphide, and gallium indium phosphide. The base substrate 112 may be referred to as a handle wafer in some embodiments. The dielectric layer 114 may include silicon oxide or other suitable insulating materials, and/or combinations thereof. In some embodiments, a dielectric layer 114 may include a buried oxide layer (BOX) that is grown or deposited overlying the silicon base substrate 112. The semiconductor layer 116 may include an elementary semiconductor, such as silicon (Si) or germanium (Ge) in a crystalline structure; a compound semiconductor, such as silicon germanium (SiGe), silicon carbide (SiC), gallium arsenic (GaAs), gallium phosphide (GaP), indium phosphide (InP), indium arsenide (InAs), and/or indium antimonide (InSb); or combinations thereof. For example, the SOI substrates are fabricated using separation by implantation of oxygen (SIMOX), wafer bonding, and/or other suitable methods. For clear illustration, in the cross-sectional views of some embodiments, the semiconductor substrate 110 is shown as including a first cantilever region CA, a second cantilever region CB, a mirror region MR, and shock buffer regions SB1, SB2, and a frame region FR, corresponding to the embodiments of FIGS. 1A-1D.

A dielectric layer 120 is deposited over the semiconductor substrate 110. The dielectric layer 120 can be made of any suitable dielectric material, such as silicon oxide, silicon nitride, the like, or the combination thereof.

An electrode layer 130 is deposited over the dielectric layer 120. The electrode layer 130 may include suitable conductive materials, such as platinum, titanium, copper (Cu), gold (Au), the like, or the combination thereof.

A piezoelectric layer 140 is deposited over the electrode layer 130. The piezoelectric layer 140 may include suitable piezoelectric materials, such as lead zirconate titanate (PZT), aluminum nitride (AlN), zinc oxide (ZnO), TiBaO₃, potassium sodium niobate ((K, Na) NbO₃, KNN)-based lead-free piezoelectric materials, the like, or the combination thereof. By using the KNN-based lead-free piezoelectric materials in the piezoelectric layer 140, the manufacturing process of the piezoelectric layer 140 could be compatible with complementary metal-oxide-semiconductor (CMOS) process, thereby maintaining good piezoelectricity.

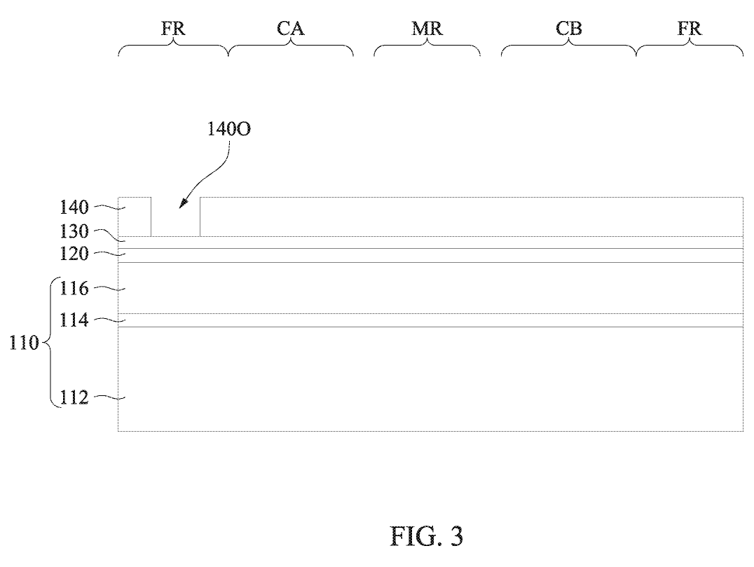

Reference is made to FIG. 3. The piezoelectric layer 140 is patterned to have one or more openings 140O exposing the underlying electrode layer 130. The patterning process may include forming a mask over the piezoelectric layer 140 by suitable photolithography process, followed by suitable etching process, such as wet etching.

Reference is made to FIGS. 4A and 4B. The second electrode layer 150 is deposited over the piezoelectric layer 140, and patterned into electrodes 152-158 (referring to FIGS. 1A-1C). The second electrode layer 150 may include suitable conductive materials, such as platinum, silver, copper (Cu), gold, chromium (Cr), the like, or the combination thereof. In some embodiments, the conductive materials of the second electrode layer 150 are chosen for achieving high reflectance in the operating wavelength range. The deposition process for the second electrode layer 150 may include an e-gun evaporation method. The patterning may include a lift-off process. After patterning, the electrode 156 (referring to FIGS. 1A-1C) may extend into the openings 140O in the piezoelectric layer 140.

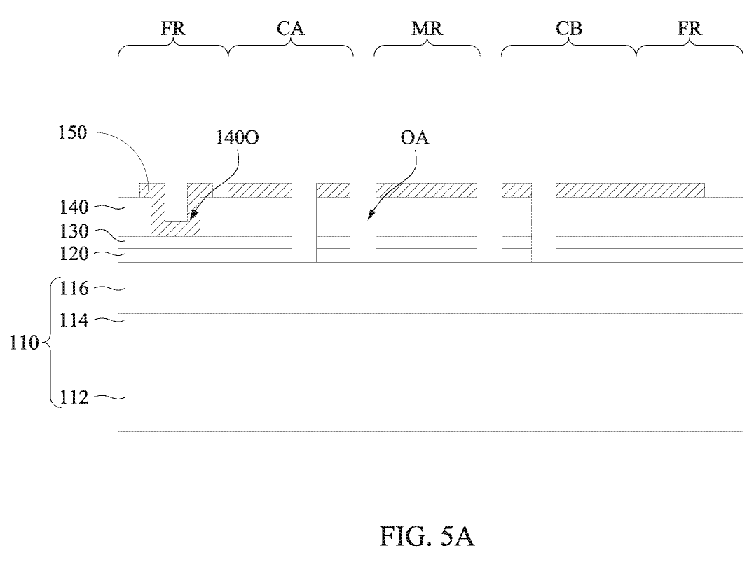

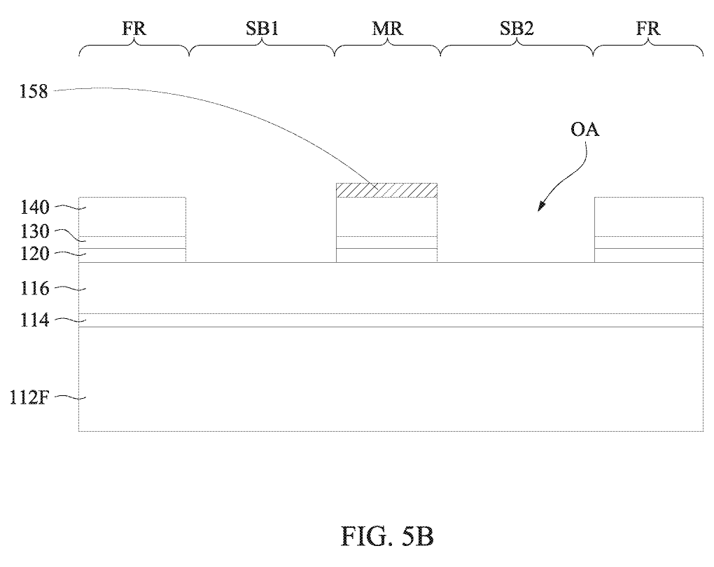

Reference is made to FIGS. 5A and 5B. The openings OA are etched in the piezoelectric layer 140, the electrode layer 130, and the dielectric layer 120. The etching process may include reactive-ion etching (RIE) process, such as an inductively coupled plasma (ICP) etching process. After the etching process, the semiconductor layer 116 may remain substantially intact. The formation of the openings OA may remove the materials of the piezoelectric layer 140, the electrode layer 130, and the dielectric layer 120 from the connection regions SPA1, SPA2, SPB1 and SPB2 and the shock buffer regions SB1, SB2.

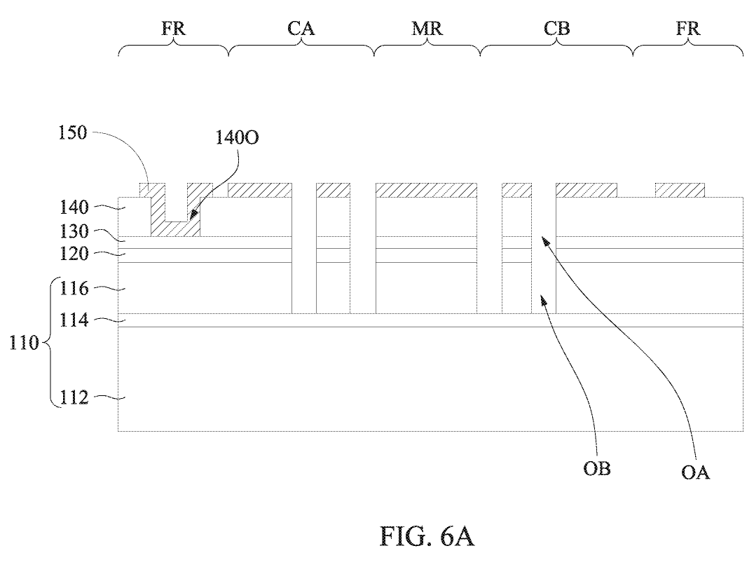

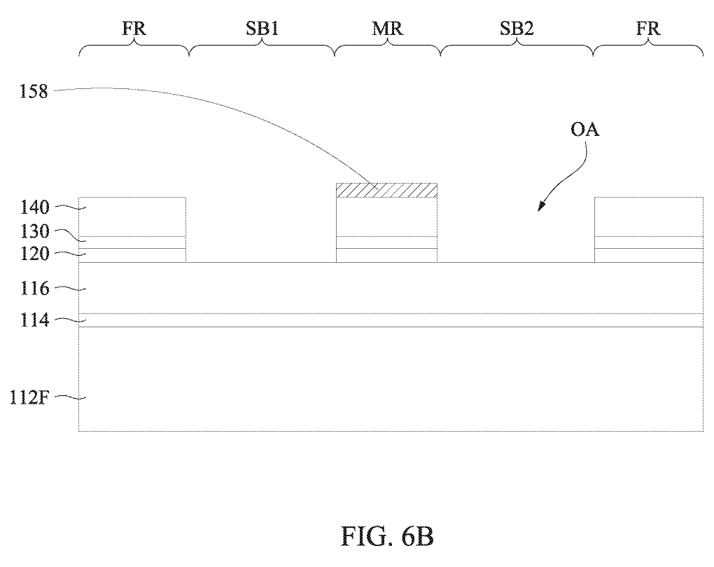

Reference is made to FIGS. 6A and 6B. Opening OB are etched in the semiconductor layer 116 exposed by the openings OA. Through the formation of the openings OA and OB, the first cantilever region CA, the second cantilever region CB, the mirror region MR, the shock buffer regions SB1, SB2, the frame region FR, the connection regions SPA1 and SPA2, and the connection regions SPB1 and SPB2 are defined.

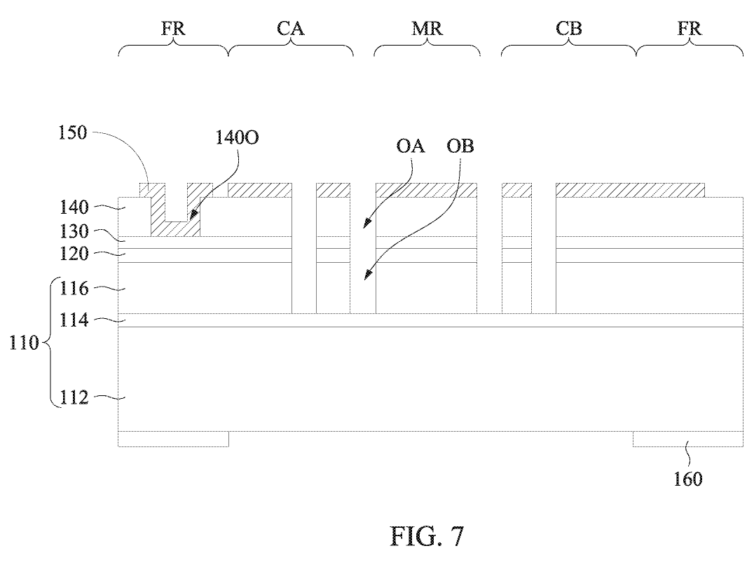

Reference is made to FIG. 7. A backside metal layer 160 is deposited at a backside of the semiconductor substrate 110, and being patterned to cover the frame region FR and exposing other regions. The backside metal layer 160 may include suitable metals, such as aluminum (Al), the like, or the combination thereof.

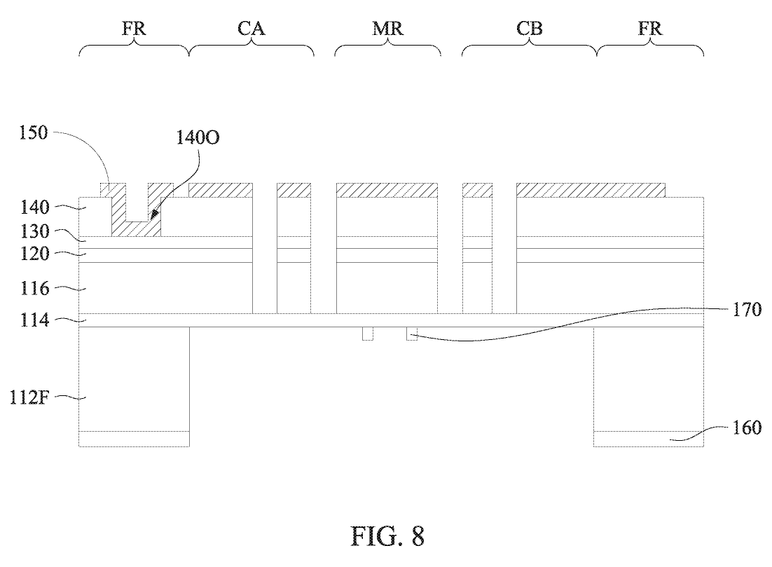

Reference is made to FIG. 8. A two-step etching process is performed to remove a portion of the base substrate 112 exposed by the backside metal layer 160, leaving the frame 112F and the rib structure 170 on the backside of the dielectric layer 114. The two-step etching process may include a first dry etch process and a second dry etch process following the first dry etch process. A photomask defining a rib pattern may be formed over the backside of the base substrate 112 through a photolithography process. The first dry etch process may etch the base substrate 112 with a suitable depth through the photomask, thereby forming a rib pattern in the base substrate 112. After the first dry etch process, the base substrate 112 has a rib pattern over the backside of the dielectric layer 114. Subsequently, the photomask is removed by suitable stripping or ashing process. Then, the second dry etch process is performed to etch the base substrate 112 using the backside metal layer 160 as an etch mask until the dielectric layer 114 is exposed. For example, once the dielectric layer 114 is exposed, the second dry etch process stops without fully remove the rib pattern, such that the remaining rib pattern forms the rib structure 170 when the dielectric layer 114 is exposed. Stated differently, the second dry etch process may etch back the rib pattern to form the rib structure 170 without using additional photomask. The first and second dry etch processes may be RIE or other suitable etching process.

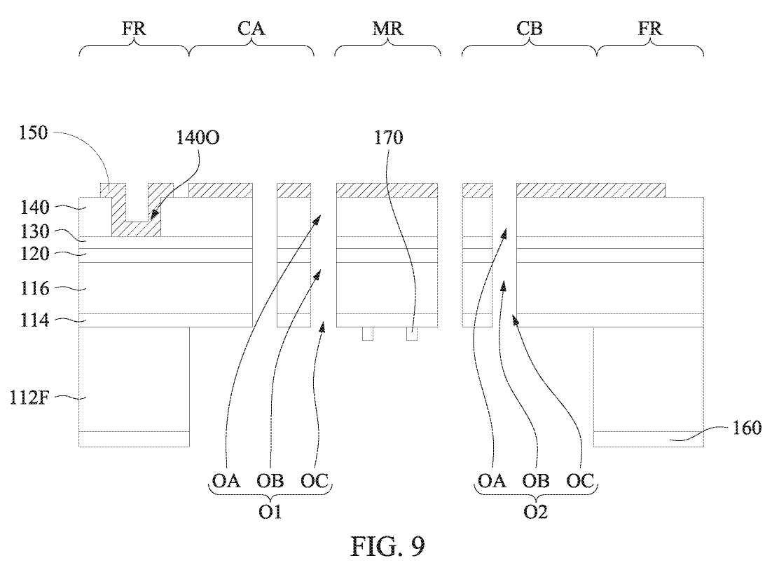

Reference is made to FIG. 9. After the formation of the rib structure 170, the dielectric layer 114 is patterned by backside dry etching process. The patterning process may include forming a photomask by photolithography process, followed by an etching process. The patterning process may form openings OC in the dielectric layer 114. The openings OC may be in communication with the openings OB and openings OA, and the combination thereof can be referred to as openings O1 and O2. Through the configuration, the mirror region MR is suspended, for example being spaced apart from the frame region FR by the first cantilever region CA, the second cantilever region CB, and the shock buffer regions SB1, SB2.

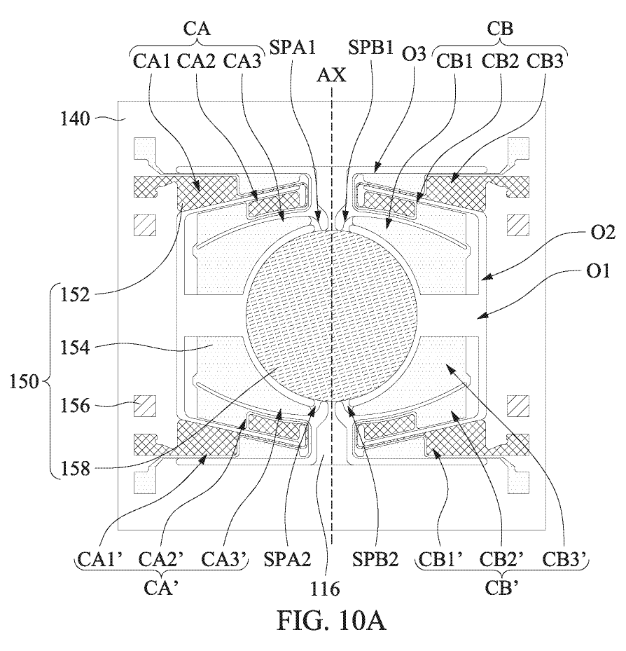

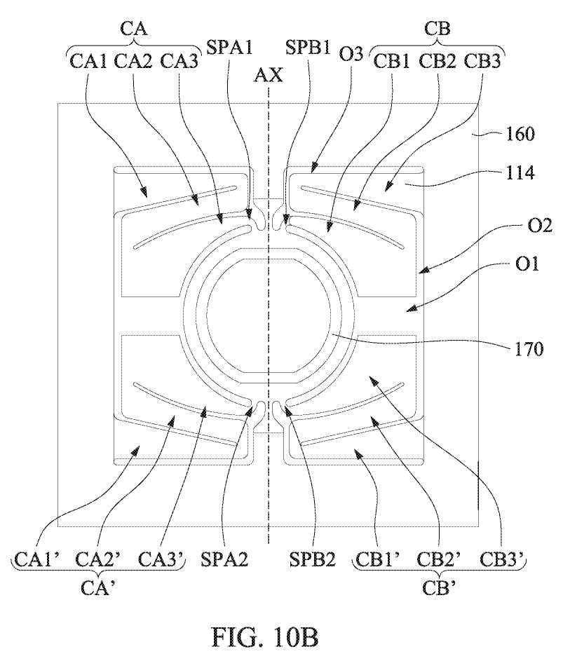

FIGS. 10A and 10B are respectively top and bottom views of a MEMS device in accordance with some embodiments of the present disclosure. Details of the present embodiments are similar to those illustrated in FIGS. 1A-1C, except that the MEMS device has four cantilever regions CA, CB, CA’, CB’, and each of the four cantilever regions CA, CB, CA’, CB’ may serve as an actuator that would deform and provide the driving force to drive the mirror when the voltage is applied on the electrodes 152, 154, and 156.

In the present embodiments, the cantilever region CA has sub-cantilever regions CA1-CA3. The sub-cantilever region CA3 is connected to the mirror region MR through the connection region SPA1. The sub-cantilever region CA1 is connected to the frame region FR. The sub-cantilever region CA2 connects the sub-cantilever region CA1 to the sub-cantilever region CA3. Each of the sub-cantilever regions CA1 and CA2 has two electrodes 152 and 154, in which the electrodes 152 of the sub-cantilever regions CA1 and CA2 are electrically connected with each other, and the electrodes 154 of the sub-cantilever regions CA1-CA3 are electrically connected with each other. Through the configuration, a large vertical displacement by accumulating the displacement of each is provided. The electrodes 152 and 154 may extend from the cantilever region CA to the frame region FR, thereby serving as conductive paths/pads for electrical connection.

Similarly, in the present embodiments, the cantilever region CA’ has sub-cantilever regions CA1’-CA3’. The sub-cantilever region CA3’ is connected to the mirror region MR through the connection region SPA1. The sub-cantilever region CA1’ is connected to the frame region FR. The sub-cantilever region CA2’ connects the sub-cantilever region CA1’ to the sub-cantilever region CA3’. Each of the sub-cantilever regions CA1’ and CA2’ has two electrodes 152 and 154, in which the electrodes 152 of the sub-cantilever regions CA1’ and CA2’ are electrically connected with each other, and the electrodes 154 of the sub-cantilever regions CA1’-CA3’ are electrically connected with each other. Through the configuration, a large vertical displacement by accumulating the displacement of each is provided. The electrodes 152 and 154 may extend from the cantilever region CA’ to the frame region FR, thereby serving as conductive paths/pads for electrical connection.

Similarly, in the present embodiments, the cantilever region CB has sub-cantilever regions CB1-CB3. The sub-cantilever region CB3 is connected to the mirror region MR through the connection region SPB1. The sub-cantilever region CB1 is connected to the frame region FR. The sub-cantilever region CB2 connects the sub-cantilever region CB1 to the sub-cantilever region CB3. Each of the sub-cantilever regions CB1 and CB2 has two electrodes 152 and 154, in which the electrodes 152 of the sub-cantilever regions CB1 and CB2 are electrically connected with each other, and the electrodes 154 of the sub-cantilever regions CB1-CB3 are electrically connected with each other. Through the configuration, a large vertical displacement by accumulating the displacement of each is provided. The electrodes 152 and 154 may extend from the cantilever region CB to the frame region FR, thereby serving as conductive paths/pads for electrical connection.

Similarly, in the present embodiments, the cantilever region CB’ has sub-cantilever regions CB1’-CB3’. The sub-cantilever region CB3’ is connected to the mirror region MR through the connection region SPB2. The sub-cantilever region CB1’ is connected to the frame region FR. The sub-cantilever region CB2’ connects the sub-cantilever region CB1’ to the sub-cantilever region CB3’. Each of the sub-cantilever regions CB1’ and CB2’ has two electrodes 152 and 154, in which the electrodes 152 of the sub-cantilever regions CB1’ and CB2’ are electrically connected with each other, and the electrodes 154 of the sub-cantilever regions CB1’-CB3’ are electrically connected with each other. Through the configuration, a large vertical displacement by accumulating the displacement of each is provided. The electrodes 152 and 154 may extend from the cantilever region CB’ to the frame region FR, thereby serving as conductive paths/pads for electrical connection. The electrodes 152/154 of the four cantilever regions CA, CB, CA’, CB’ can be applied with different voltages for individually operation and control. Other details of the present embodiments are similar to those illustrated above, and thereto not repeated herein.

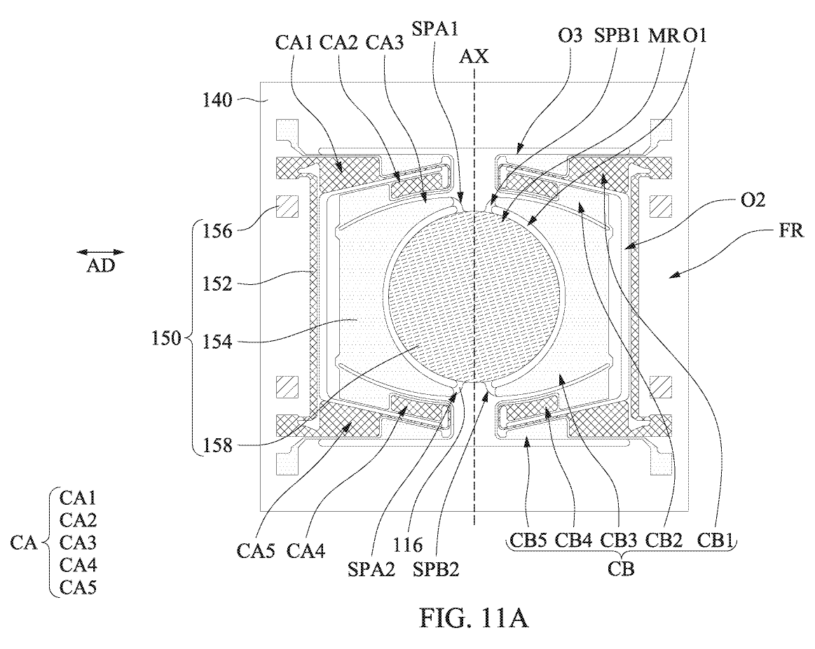

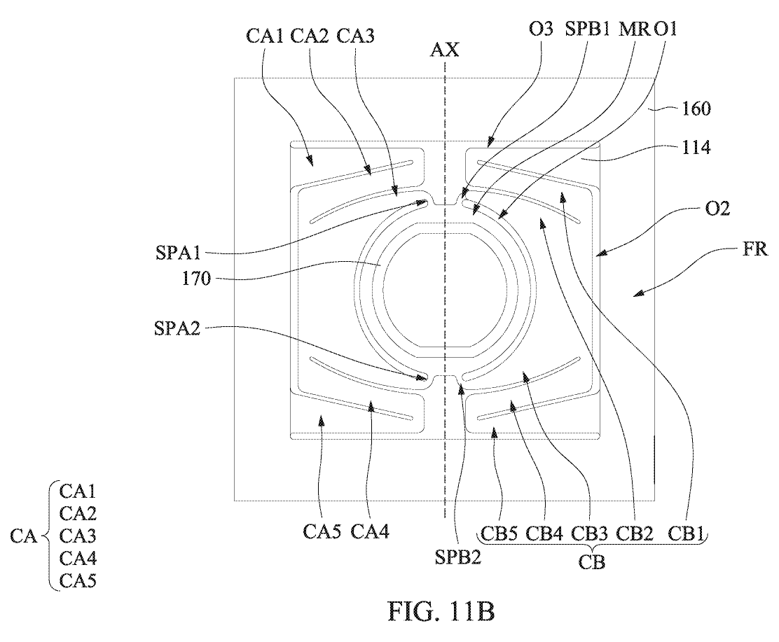

FIGS. 11A and 11B are respectively top and bottom views of a MEMS device in accordance with some embodiments of the present disclosure. Details of the present embodiments are similar to those illustrated in FIGS. 1A-1C, except that the shock buffer regions SB1 and SB2 (referring to FIGS. 1A-1C) are omitted in the present embodiments. Other details of the present embodiments are similar to those illustrated above, and thereto not repeated herein.

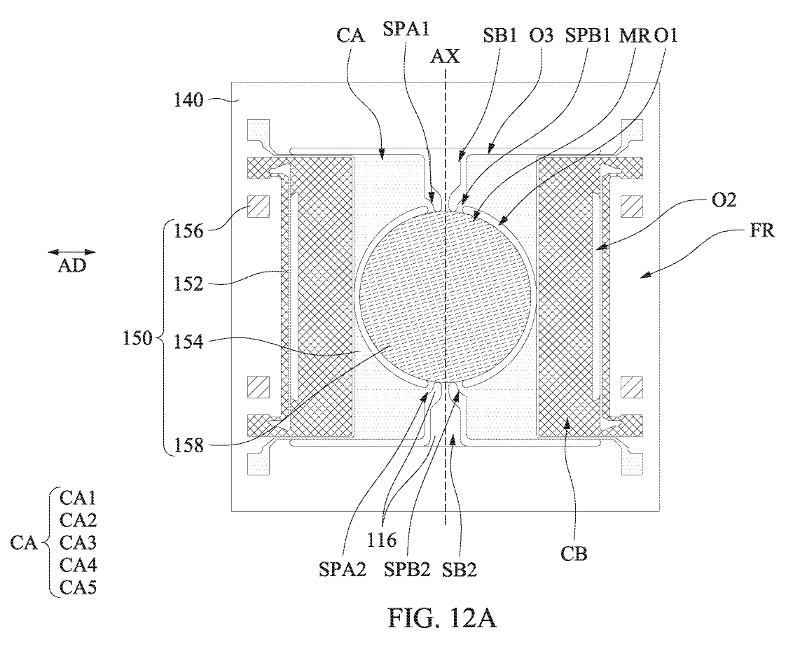

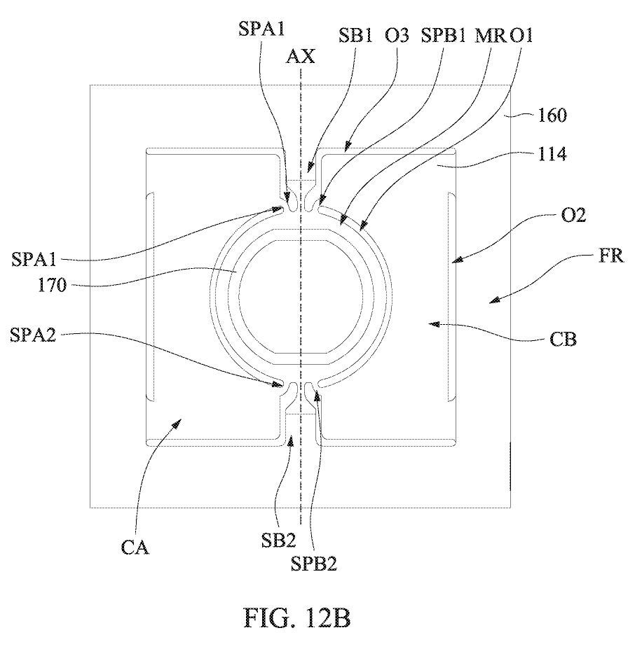

FIGS. 12A and 12B are respectively top and bottom views of a MEMS device in accordance with some embodiments of the present disclosure. Details of the present embodiments are similar to those illustrated in FIGS. 1A-1C, except that the openings O2 and O3 may not extend into the first cantilever region CA and the second cantilever region CB in the present embodiments. Thus, the first cantilever region CA may be an intact cantilever connected between the frame region FR and connection regions SPA1 and SPA2. And, the second cantilever region CB may be an intact cantilever connected between the frame region FR and connection regions SPB1 and SPB2. The first cantilever region CA and the second cantilever region CB may not have plural sub-cantilever regions as shown in FIGS. 1A-1C. With the configuration, the first cantilever region CA and the second cantilever region CB have higher strength, thereby allowing higher resonant frequency. Other details of the present embodiments are similar to those illustrated above, and thereto not repeated herein.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the multi-cantilever actuator provides a large output displacement to the torsional mode of scanning mirror, thereby achieving good optical scanning angle. Another advantage is that the multi-cantilever actuators could enhance the robustness of the device and avoid lateral shift issue. Still another advantage is that the design of the shock buffer can increase the robustness of the out-of-plane of the mirror and reduce the wobbling phenomenon. Still another advantage is that the signal to noise ratio sufficiently high enough for long-range detection, resonant frequency is high enough for faster scan speed, and the vibration from the working environment can be tolerated.

In some embodiments of the present disclosure, a microelectromechanical systems (MEMS) device includes a mirror structure, a frame, a first cantilever and a second cantilever. The mirror structure is suspended in the frame by the first cantilever and the second cantilever. The first cantilever includes a first sub-cantilever connected to the frame; a second sub-cantilever connected to the mirror structure; and a third sub-cantilever connecting the first sub-cantilever to the second sub-cantilever. Each of the first sub-cantilever and the third sub-cantilever comprises a first bottom electrode; a first piezoelectric layer over the first bottom electrode; and first and second top electrodes over the first piezoelectric layer, wherein the first and second top electrodes are separated from each other.

In some embodiments of the present disclosure, a MEMS device includes a mirror structure; a frame; a first shock buffer and a second shock buffer connecting the mirror structure to the frame, wherein the first and second shock buffers extend along a rotation axis of the mirror structure; a first cantilever and a second cantilever, wherein the mirror structure is suspended in the frame by the first cantilever and the second cantilever; a first connection spring adjacent the first shock buffer and connecting the first cantilever to the mirror structure; a second connection spring adjacent the first shock buffer and connecting the second cantilever to the mirror structure, wherein the first connection spring and the second connection spring are spaced apart from the rotation axis of the mirror structure in a top view.

In some embodiments of the present disclosure, a method for forming a MEMS device is provided. The method includes depositing a first electrode layer over the semiconductor substrate; depositing a piezoelectric layer over the first electrode layer; depositing a second electrode layer over the piezoelectric layer; patterning the second electrode layer at least into a first electrode, a second electrode, and a mirror; and etching the piezoelectric layer and the first electrode layer to form at least a first cantilever region, a second cantilever region, a mirror region, and a frame region, wherein the mirror region is suspended by the first cantilever region, the second cantilever region, and the frame region, and the first cantilever region comprises: a first sub-cantilever region; a second sub-cantilever region, wherein each of the first sub-cantilever region and the second sub-cantilever region comprises the first electrode and the second electrode; and a third sub-cantilever region, wherein the third sub-cantilever region is connected to the mirror region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A microelectromechanical systems (MEMS) device, comprising:
a mirror structure;
a frame;
a first cantilever and a second cantilever, wherein the mirror structure is suspended in the frame by the first cantilever and the second cantilever, each of the first cantilever and the second cantilever comprises a bottom electrode, a piezoelectric layer over the bottom electrode, and first and second top electrodes over the piezoelectric layer;
a first connection spring connecting the first cantilever to the mirror structure; and
a second connection spring connecting the second cantilever to the mirror structure.

2. The MEMS device of claim 1, further comprising:
a first shock buffer and a second shock buffer connecting the mirror structure to the frame, wherein the first and second shock buffers extend along a rotation axis of the mirror structure.

3. The MEMS device of claim 2, wherein the first connection spring is laterally aligned with the first shock buffer in a top view, and the second connection spring is laterally aligned with the first shock buffer in the top view.

4. The MEMS device of claim 2, wherein a width of the first and second shock buffers increases from the mirror structure to the frame.

5. The MEMS device of claim 1, wherein the first cantilever has a plurality of first sub-cantilevers, a width of the first connection spring is less than a width of the first sub-cantilevers.

6. The MEMS device of claim 1, wherein the second cantilever has a plurality of second sub-cantilevers, and a width of the second connection spring is less than a width of the second sub-cantilevers.

7. The MEMS device of claim 1, wherein the first connection spring and the second connection spring are free of the first and second top electrodes, the piezoelectric layer, and the bottom electrode.

8. The MEMS device of claim 1, wherein a length of the first top electrode measured along a direction parallel with a rotation axis of the mirror structure is greater than a length of the mirror structure measured along the rotation axis of the mirror structure in a top view.

9. A microelectromechanical systems (MEMS) device, comprising:
a mirror structure;
a frame;
a first cantilever and a second cantilever, wherein the mirror structure is suspended in the frame by the first cantilever and the second cantilever;
a first connection spring connecting the first cantilever to the mirror structure; and
a second connection spring connecting the second cantilever to the mirror structure,
wherein the first cantilever comprises a plurality of sub-cantilevers, lengthwise directions of the sub-cantilevers are angled at respective angles relative to a direction orthogonal to a rotation axis of the mirror structure in a top view, and the angle of a first one of the sub-cantilevers nearer the mirror structure is greater than the angle of a second one of the sub-cantilevers farther from the mirror structure.

10. The MEMS device of claim 9, wherein each of the sub-cantilevers has an elongated shape extending along the direction orthogonal to the rotation axis.

11. The MEMS device of claim 9, wherein the angle of the first one of the sub-cantilevers is in a range from about 10 degrees to about 20 degrees in the top view, and the angle of the second one of the sub-cantilevers is in a range from about 0 degrees to about 10 degrees in the top view.

12. The MEMS device of claim 9, wherein the second cantilever comprises a plurality of sub-cantilevers symmetric to the sub-cantilevers of the first cantilever.

13. The MEMS device of claim 9, further comprising:
a rib structure underlying the mirror structure.

14. The MEMS device of claim 9, wherein the first cantilever comprises a bottom electrode, a piezoelectric layer over the bottom electrode, and first and second top electrodes over the piezoelectric layer.

15. The MEMS device of claim 9, further comprising:
a shock buffer connecting the mirror structure to the frame, the shock buffer extending along the rotation axis of the mirror structure.

16. A microelectromechanical systems (MEMS) device, comprising:
a mirror structure;
a frame;
a first cantilever, a second cantilever, a third cantilever, and a fourth cantilever, wherein the mirror structure is suspended in the frame by the first cantilever, the second cantilever, the third cantilever, and the fourth cantilever, and the first cantilever, the second cantilever, the third cantilever, and the fourth cantilever are electrically isolated from each other;
a first connection spring connecting the first cantilever to the mirror structure;
a second connection spring connecting the second cantilever to the mirror structure;
a third connection spring connecting the third cantilever to the mirror structure; and
a fourth connection spring connecting the fourth cantilever to the mirror structure,
wherein each of the first cantilever, the second cantilever, the third cantilever, and the fourth cantilever comprises a plurality of sub-cantilevers.

17. The MEMS device of claim 16, wherein the first connection spring and the third connection spring are at opposite sides of the mirror structure along a rotation axis of the mirror structure.

18. The MEMS device of claim 16, wherein electrodes of the sub-cantilevers of the first cantilever are electrically connected with each other, and electrodes of the sub-cantilevers of the second cantilever are electrically connected with each other.

19. The MEMS device of claim 16, wherein at least one of the sub-cantilevers of the first cantilever comprises a bottom electrode, a piezoelectric layer over the bottom electrode, and first and second top electrodes over the piezoelectric layer.

20. The MEMS device of claim 16, further comprising:
a shock buffer connecting the mirror structure to the frame, wherein the shock buffer is spaced apart from the first connection spring, the second connection spring, the third connection spring, and the fourth connection spring.
